(19) United States
(12) Patent Application Publication
(10) Pub. No.: US 2024/0001561 A1
(43) Pub. Date: Jan. 4, 2024

(54) HAND FOR INDUSTRIAL ROBOT AND INDUSTRIAL ROBOT

(71) Applicant: NIDEC SANKYO CORPORATION, Nagano (JP)

(72) Inventor: Shigeyuki KAINO, Nagano (JP)

(73) Assignee: NIDEC SANKYO CORPORATION, Nagano (JP)

(21) Appl. No.: 18/029,665

(22) PCT Filed: Sep. 15, 2021
(86) PCT No.: PCT/JP2021/033964

§ 371 Date: Mar. 31, 2023

(30) Foreign Application Priority Data
Oct. 2, 2020 (JP) 2020-167858

(51) Int. Cl. B25J 11/00; B25J 15/00; B25J 15/06

(52) U.S. Cl. CPC B25J 11/0095; B25J 15/0014; B25J 15/0616

(57) ABSTRACT

A hand for an industrial robot allowing use thereof in different ways for different applications while reducing manufacturing costs and an industrial robot including the hand are provided. A hand includes a support portion configured to support either a suction wafer mounting portion or a grip wafer mounting portion, and the support portion includes an air flow path connected to a suction hole in a state where the support portion supports the suction wafer mounting portion and one of a suction unit including a connecting member that connects a tip end of an air pipe to the air flow path and a grip unit that can press an end surface of a wafer in a state where the support portion supports the grip wafer mounting portion, and further includes an attachment portion used for attaching the other one of the suction unit and the grip unit.

### TECHNICAL FIELD

This invention relates to a hand for an industrial robot and an industrial robot including the hand.

### BACKGROUND ART

Conventionally, industrial robots that convey objects to be conveyed, such as semiconductor wafers or the like, have been known. For example, Patent Literature 1 describes an industrial robot including four hands on which an object to be conveyed is mounted, an arm to which the four hands are pivotably connected on a tip end thereof, and a body portion to which a base end of the arm is pivotably connected. In the industrial robot, when it is assumed that the four hands are designated as a first hand pair and a second hand pair, a holding portion of the two hands serving as one of the first hand pair and the second hand pair includes an end surface abutting member having an abutting surface that an end surface of the object to be conveyed abuts and a pressing mechanism that presses the object to be conveyed such that the end surface of the object to be conveyed is pressed against the abutting surface. A holding portion of the two hands serving as the other one of the first hand pair and the second hand pair includes a suction hole to suck and hold the object to be conveyed.

### CITATION LIST

### Patent Literature

[Patent Literature 1] Japanese Unexamined Patent Application Publication No. 2017-119326

### SUMMARY OF THE INVENTION

### Problems to be Solved by the Invention

As methods for holding a semiconductor wafer in an industrial robot, a grip holding method in which an end surface (outer peripheral surface) of a wafer is pressed and held and a suction holding method in which a wafer is sucked to be held have been known, as in Patent Literature 1. In some cases, even in the same industrial robot, it is desired to switch between the grip holding method and the suction holding method, depending on an application thereof. Therefore, it is conceivable to manufacture a hand that incorporates both a unit used for the grip holding method and a unit used for the suction holding method. However, such a hand requires higher manufacturing costs, resulting in higher sales price to users. Therefore, a user who does not need one of the units has to pay an extra fee.

It is an object of the present invention is to provide a hand for an industrial robot allowing use thereof in different ways for different applications while reducing manufacturing costs and an industrial robot including the hand.

### Means for Solving the Problem

A hand for an industrial robot according to one aspect of the present invention is a hand for an industrial robot which includes a first mounting portion on which an object to be conveyed is mounted and that has an end surface abutting member including an abutting surface that an end surface of the object to be conveyed abuts and a second mounting portion on which an object to be conveyed is mounted and that has a suction hole through which the object to be conveyed is sucked to be held, the first mounting portion and the second mounting portion being configured to be replaceable with each other and includes a support portion configured to support either the first mounting portion or the second mounting portion, and the support portion includes an air flow path connected to the suction hole in a state where the support portion supports the second mounting portion, one of a first unit including a connecting member that connects a tip end of an air pipe stored in the industrial robot to the air flow path and a second unit that can press an end surface of the object to be conveyed that is mounted on the first mounting portion in a state where the support portion supports the first mounting portion, and an attachment portion used for attaching the other one of the first unit and the second unit.

An industrial robot according to one aspect of the present invention includes the hand, the air pipe, an arm that supports the hand, and an arm support portion that supports the arm.

### Effect of the Invention

According to the present invention, it is possible to provide a hand for an industrial robot allowing use thereof in different ways for different applications while reducing manufacturing costs and an industrial robot including the hand.

### BRIEF DESCRIPTION OF THE DRAWINGS

FIG. 1 is a view illustrating a schematic configuration of a manufacturing system according to an embodiment of the present invention, as viewed from front.

FIG. 2 is a view illustrating a schematic configuration of the manufacturing system illustrated in FIG. 1 as viewed from top.

FIG. 3 is a side view of a horizontal articulated robot illustrated in FIG. 1.

FIG. 4 is a side view of the horizontally articulated robot illustrated in FIG. 3 with an arm support portion lifted.

FIG. 5 is a plan view of the horizontal articulated robot illustrated in FIG. 3.

FIG. 6 is a schematic view illustrating a detailed configuration near a support portion of a hand illustrated in FIG. 5.

FIG. 7 is a schematic view illustrating a state where a grip unit is attached to the support portion of FIG. 6.

FIG. 8 is a schematic view illustrating a state where a grip wafer mounting portion is loaded to the support portion in the state illustrated in FIG. 7.

FIG. 9 is a schematic view illustrating a state where a suction wafer mounting portion is loaded to the support portion in the state illustrated in FIG. 7.

FIG. 10 is a schematic view illustrating an internal configuration of a holding portion illustrated in FIG. 3.

FIG. 11 is a cross-sectional view illustrating the internal configuration of the holding portion illustrated in FIG. 3.

### MODE FOR CARRYING OUT THE INVENTION

Embodiments of the present invention will be described below with reference to the accompanying drawings.

Overall Configuration of Manufacturing System

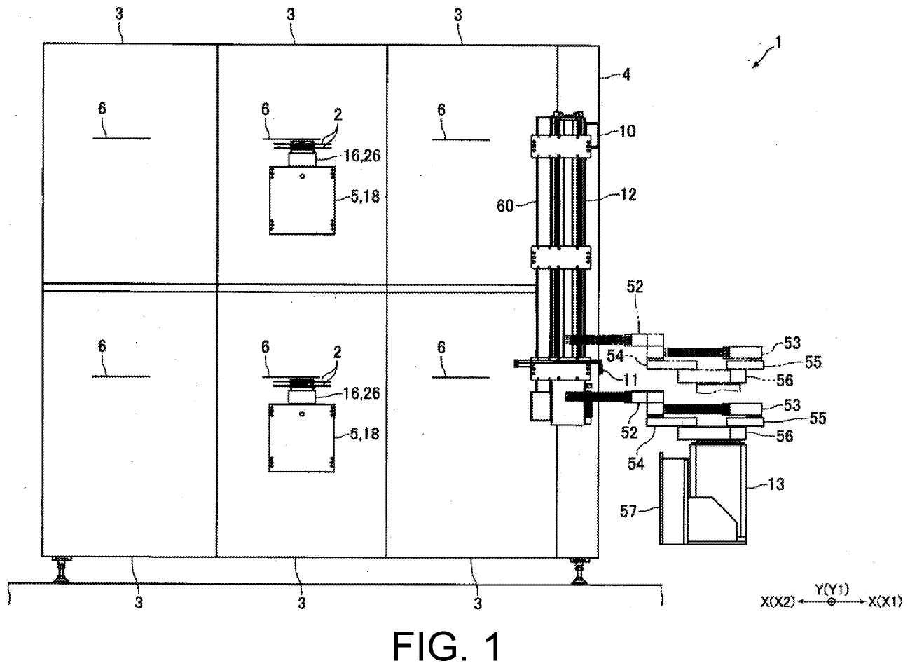

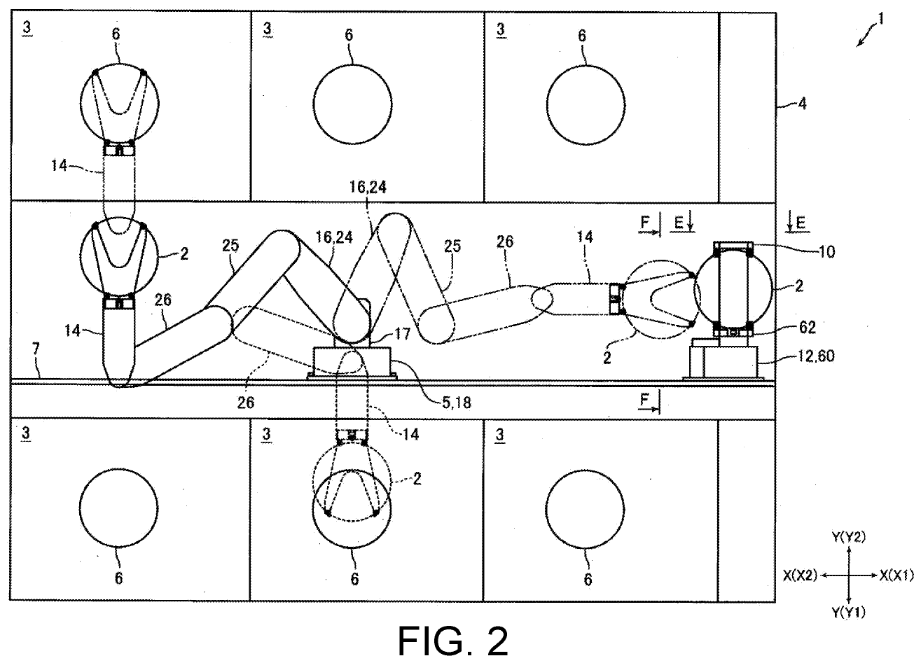

FIG. 1 is a view illustrating a schematic configuration of a manufacturing system 1 according to an embodiment of the present invention as viewed from front. FIG. 2 is a view illustrating the schematic configuration of the manufacturing system 1 illustrated in FIG. 1 as viewed from top.

The manufacturing system 1 of this embodiment is a semiconductor manufacturing system used for manufacturing semiconductors. The manufacturing system 1 includes a processing unit 4 having a plurality of processing devices 3 that execute predetermined processing on a semiconductor wafer 2 (which will be hereinafter referred to as a “wafer 2”). The processing unit 4 includes a plurality of floors, and a plurality of processing devices 3 are installed in each of the plurality of floors. The manufacturing system 1 includes a horizontally articulated robot 5 (which will be hereinafter referred to as “robot 5”) that is installed in each floor of the processing unit 4 and conveys the wafer 2 in and out of the processing devices 3. The wafer 2 in this embodiment is an object to be conveyed by the robot 5.

In the following description, an X direction that is orthogonal to an up-down direction in FIG. 1 or the like is referred to as a “left-right” direction, and a Y direction that is orthogonal to the up-down direction and the left-right direction in FIG. 1 or the like is referred to as a “front-rear” direction. Moreover, an X1 direction side in the left-right direction is a “right” side, an X2 direction side that is an opposite side thereto is a “left” side, and a Y1 direction side in the front-rear direction is a “front” side, and a Y2 direction side that is an opposite side thereto is a “back (rear)” side.

The processing unit 4 in this embodiment includes two floors, as illustrated in FIG. 1. One robot 5 is installed on each of a first floor of the processing unit 4 and a second floor of the processing unit 4. The robots 5 are installed inside the processing unit 4. In addition, for example, six processing devices 3 are installed on each of the first floor and the second floor of the processing unit 4. Specifically, as illustrated in FIG. 2, in each of the first floor and the second floor of the processing unit 4, three processing devices 3 that are arranged adjacent to each other in the left-right direction are installed at each of two locations with a predetermined distance therebetween in the front-rear direction. Each of the processing devices 3 includes a wafer placing portion 6 on which the wafer 2 is placed.

Each of the robots 5 is installed between the three processing devices 3 arranged in a front side and the three processing devices 3 arranged in a rear side on a corresponding one of the first floor and the second floor of the processing unit 4. The robot 5 is installed in a central position of the processing unit 4 in the left-right direction on the corresponding one of the first floor and the second floor of the processing unit 4. On each of the first floor and the second floor of the processing unit 4, a fixing frame 7 that fixes a corresponding one of the robots 5 is provided and the robot 5 is fixed to the fixing frame 7.

The manufacturing system 1 has a lifting device 12 including two storage portions 10 and 11 in which the plurality of wafers 2 are stored. The lifting device 12 is installed on a right end of an inside of the processing unit 4. The lifting device 12 is arranged approximately in the same position as the robots 5 in the front-rear direction. The lifting device 12 is fixed to the fixing frames 7. The manufacturing system 1 includes a horizontally articulated robot 13 (see FIG. 1) that is arranged with the lifting device 12 interposed between the horizontally articulated robot 13 and the robots 5 in the left-right direction when viewed from the up-down direction. The horizontally articulated robot 13 will be hereinafter referred to as a “robot 13.” The robot 13 is installed outside the processing unit 4 and is arranged approximately in the same position as the lifting device 12 in the front-rear direction. The robot 13 is not illustrated in FIG. 2.

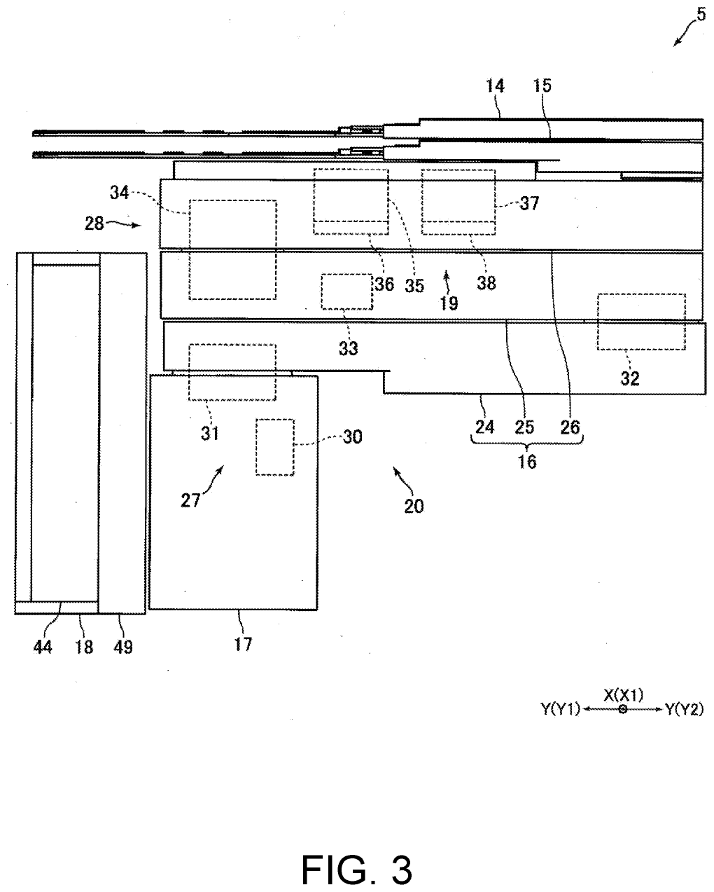

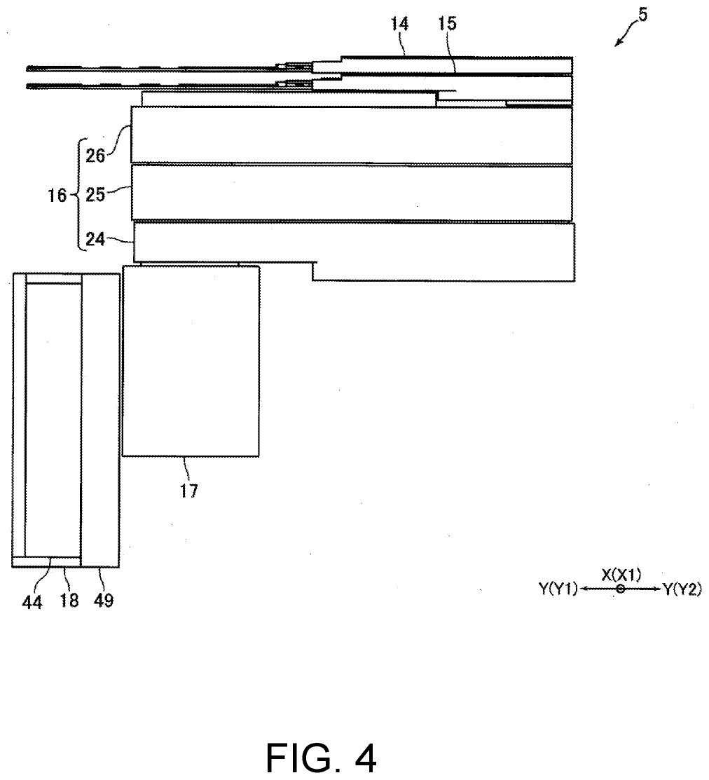

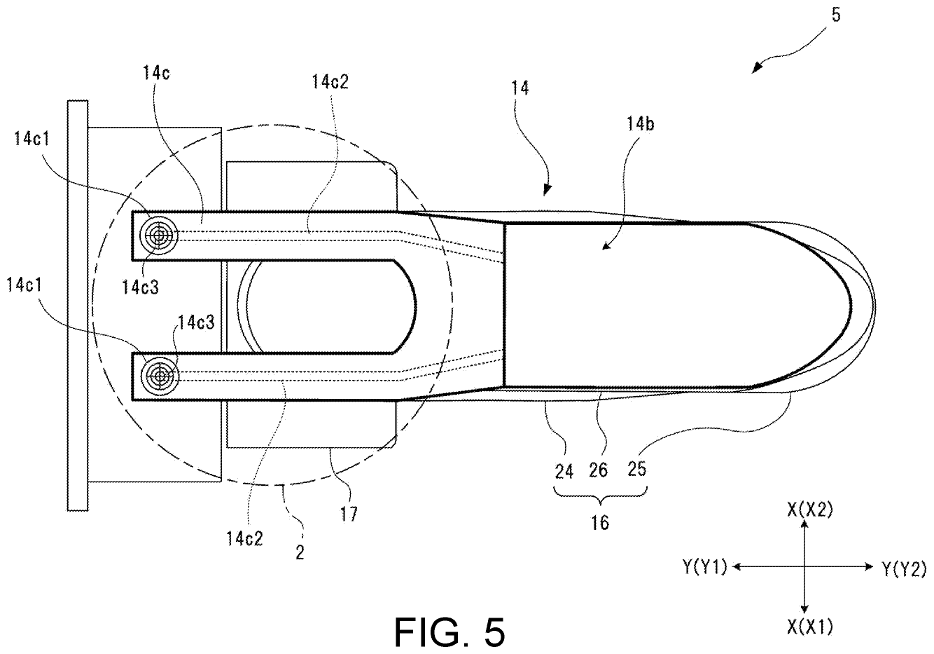

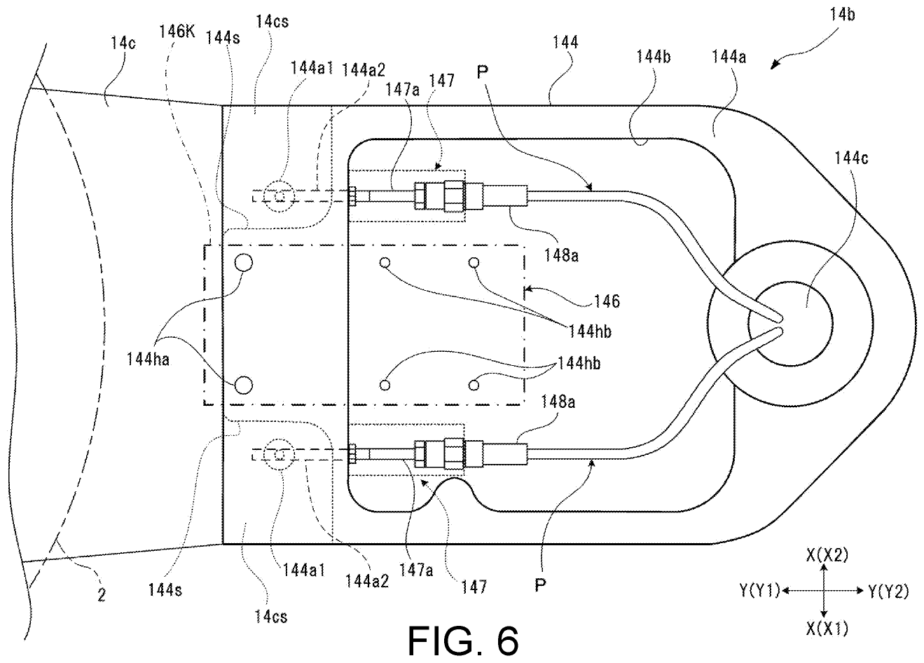

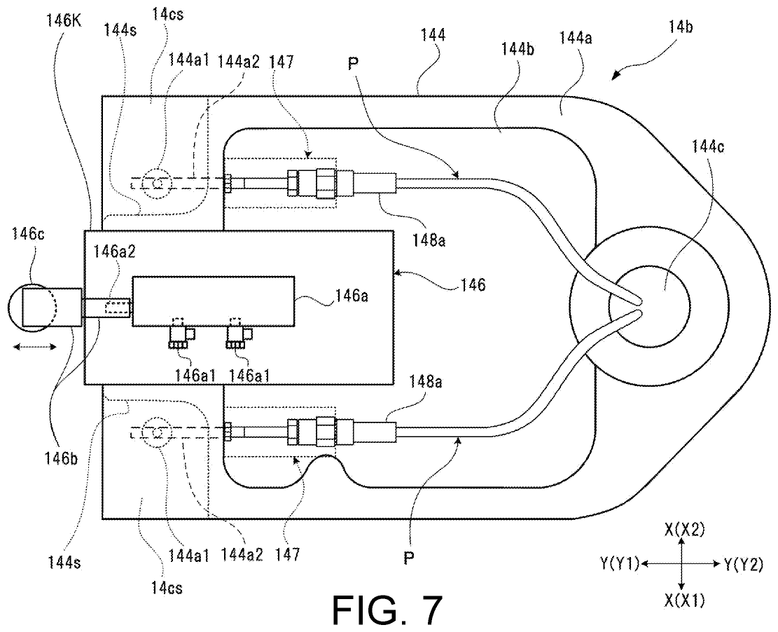

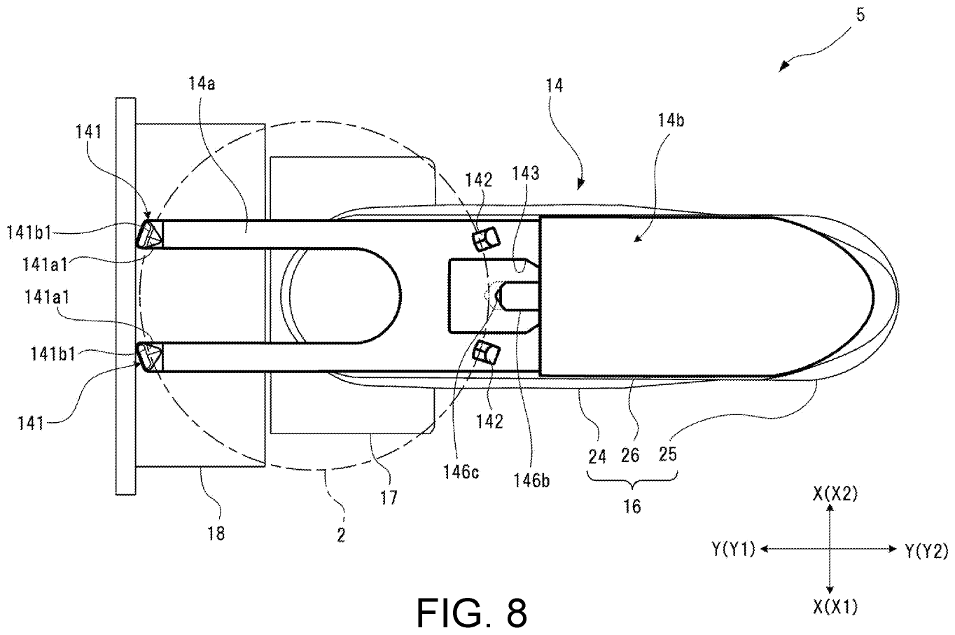

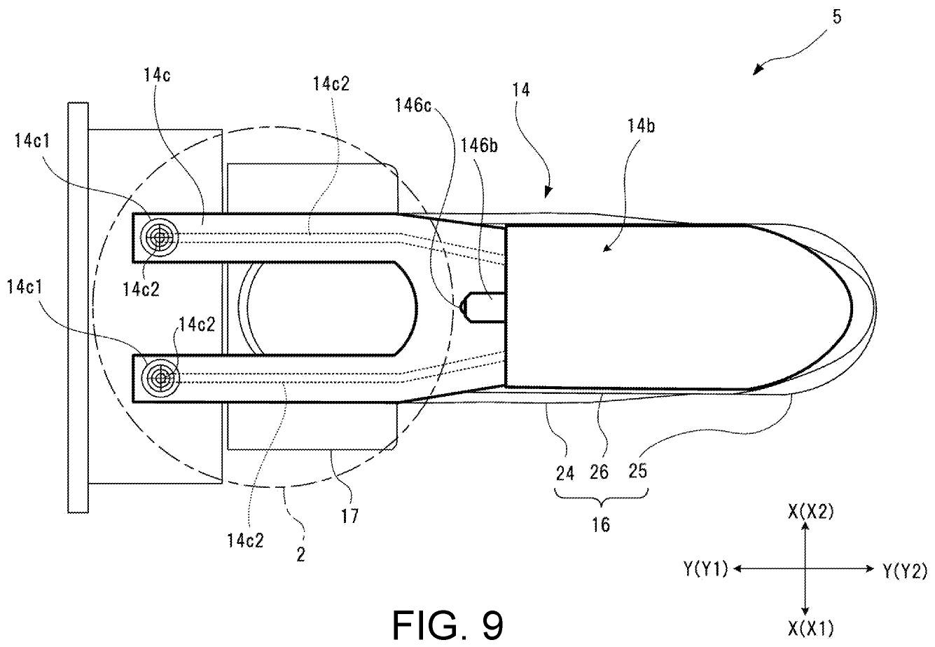

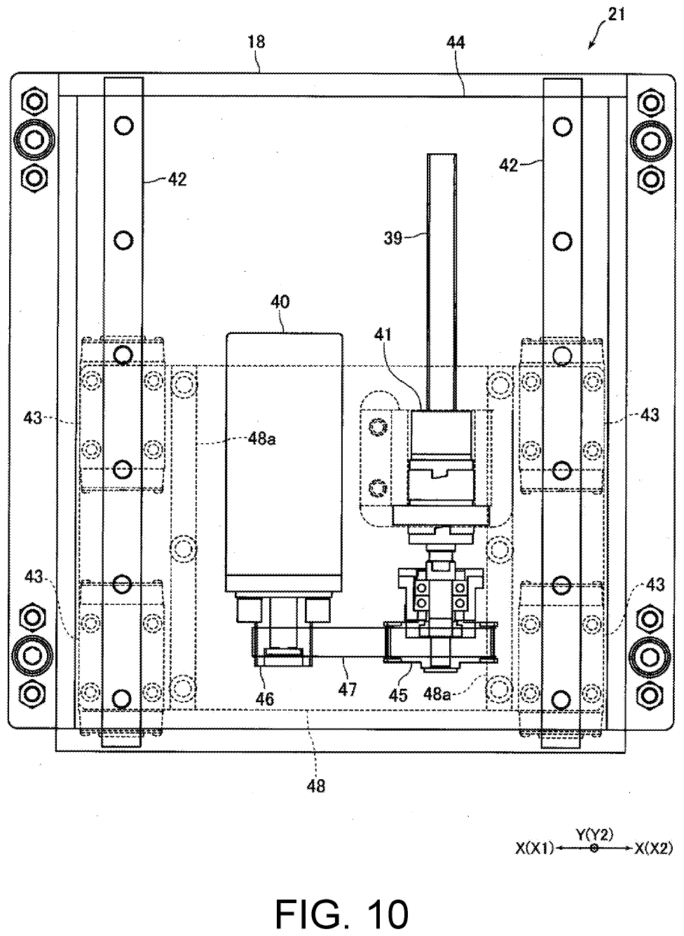

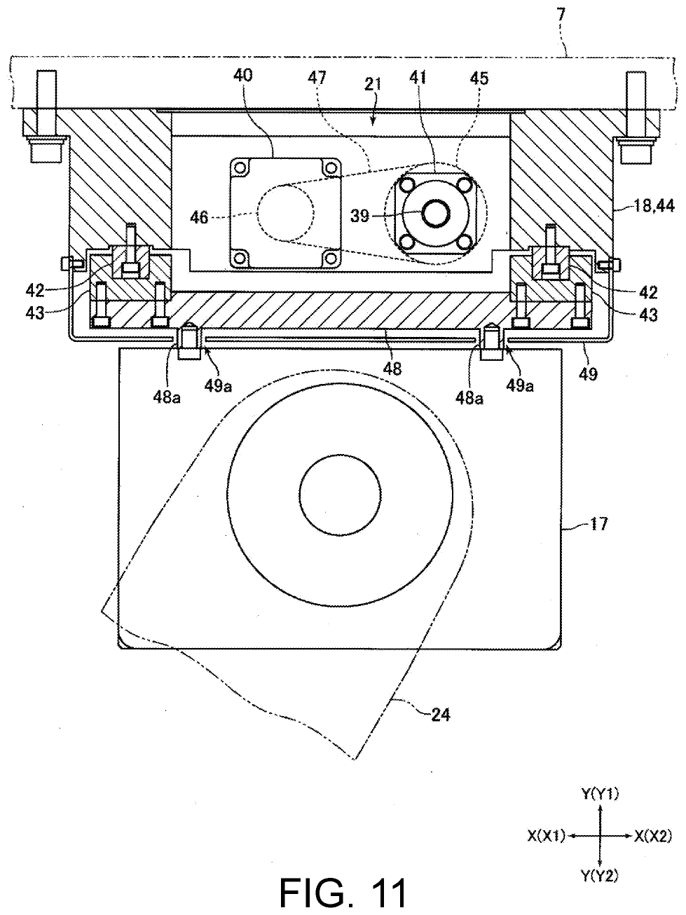

Configuration of Horizontally Articulated Robot FIG. 3 is a side view of the robot 5 illustrated in FIG. 1. FIG. 4 is a side view of the robot illustrated in FIG. 3 with an arm support portion 17 lifted. FIG. 5 is a plan view of the robot 5 illustrated in FIG. 3. FIG. 6 is a schematic view illustrating a detailed configuration near a support portion 14b of a hand 14 illustrated in FIG. 5. FIG. 7 is a schematic view illustrating a state where a grip unit 146 is attached to the support portion 14b in FIG. 6. FIG. 8 is a schematic view illustrating a state where a grip wafer mounting portion 14a is loaded to the support portion 14b in the state illustrated in FIG. 7. FIG. 9 is a schematic view illustrating a state where a suction wafer mounting portion 14c is loaded to the support portion 14b in the state illustrated in FIG. 7. FIG. 10 is a schematic view illustrating an internal configuration of a holding portion 18 illustrated in FIG. 3. FIG. 11 is a cross-sectional view illustrating the internal configuration of the holding portion 18 illustrated in FIG. 3.

The robot 5 is a three-link arm type robot. The robot 5 includes two hands 14 and 15 on which the wafers 2 are mounted, an arm 16 to which the hands 14 and 15 are pivotably connected at a tip end thereof and that moves horizontally, the arm support portion 17 to which a base end of the arm 16 is pivotably connected, and the holding portion 18 that holds the arm support portion 17 such that the arm support portion 17 can move up and down. The robot 5 also includes a hand driving mechanism 19 that causes the hands 14 and 15 to pivot relative to the arm 16 and an arm driving mechanism 20 that drives the arm 16 (see FIG. 3). The robot 5 also includes an arm lifting mechanism 21 that causes the arm support portion 17 to move up and down relative to the holding portion 18 (see FIG. 10 and FIG. 11).

The arm 16 includes a first arm portion 24 whose base end is pivotably connected to the arm support portion 17, a second arm portion 25 whose base end is pivotably connected to a tip end of the first arm portion 24, and a third arm portion 26 whose base end is pivotably connected to a tip end of the second arm portion 25. That is, the arm 16 includes three arm portions that are relatively pivotably connected to each other. Each of the first arm portion 24, the second arm portion 25, and the third arm portion 26 is formed into a hollow shape. The arm support portion 17, the first arm portion 24, the second arm portion 25, and the third arm portion 26 are arranged in this order from bottom in the up-down direction.

The hands 14 and 15 are formed such that each of respective shapes thereof when viewed from the up-down direction is approximately a Y-shape. The hands 14 and 15 are arranged such that a base end portion of the hand 14 and a base end portion of the hand 15 superimpose each other in the up-down direction. The hand 14 is arranged at an upper side and the hand 15 is arranged at a lower side. The base end portions of the hands 14 and 15 are pivotably connected to a tip end of the third arm portion 26. A top surface of the tip side portions of the hands 14 and 15 is a mounting surface on which the wafer 2 is mounted, and a single wafer 2 is mounted on the top surface of the tip side portions of the hands 14 and 15. The hands 14 and 15 are arranged above the third arm portion 26.

In FIG. 2, the hand 15 is not illustrated. During operation of the robot 5 of this embodiment, in most cases, the hand 14 and hand 15 do not superimpose each other in the up-down direction, although there are cases where the hand 14 and hand 15 superimpose each other in the up-down direction. For example, as illustrated by a chain double-dashed line in FIG. 2, while the hand 14 is entering the processing device 3, the hand 15 is rotating toward the arm support portion 17 and is not in the processing device 3. The rotating angle of the hand 15 relative to the hand 14 then is, for example, 120 degrees to 150 degrees.

The holding portion 18 is formed into an approximately rectangular parallelepiped box shape. Upper and lower end surfaces of the holding portion 18 are planes orthogonal to the up-down direction. Both front and rear side surfaces of the holding portion 18 are planes orthogonal to the front-rear direction, and both left and right side surfaces of the holding portion 18 are planes orthogonal to the left-right direction. As described above, the robot 5 is fixed to the fixing frame 7 of the processing unit 4. In this embodiment, a front side surface of the holding portion 18 is fixed to the fixing frame 7. That is, the front side surface of the holding portion 18 is fixed to the processing unit 4.

The arm support portion 17 is formed into an approximately rectangular parallelepiped box shape. Upper and lower end surfaces of the arm support portion 17 are planes orthogonal to the up-down direction. Both front and rear side surfaces of the arm support portion 17 are planes orthogonal to the front-rear direction, and both left and right side surfaces of the arm support portion 17 are planes orthogonal to the left-right direction. A base end of the first arm portion 24 is pivotably connected to the upper end surface of the arm support portion 17. The arm support portion 17 is arranged behind the holding portion 18, and the arm support portion 17 and the holding portion 18 are displaced from each other in the front-rear direction. The arm support portion 17 can move up and down along a rear side surface of the holding portion 18. The arm support portion 17 has a height (a length in the up-down direction) lower than a height (a length in the up-down direction) of the holding portion 18.

As illustrated in FIG. 3, the arm driving mechanism 20 includes a first driving mechanism 27 that causes the first arm portion 24 and the second arm portion 25 to pivot together such that the arm 16 extends and retracts and a second driving mechanism 28 that causes the third arm portion 26 to pivot relative to the second arm portion 25. The first driving mechanism 27 includes a motor 30, a speed reducer 31 that reduces speed of power of the motor 30 and transmits the power to the first arm portion 24, and a speed reducer 32 that reduces the power of the motor 30 and transmits the power to the second arm portion 25. The second driving mechanism 28 includes a motor 33 and a speed reducer 34 that reduces speed of power of the motor 33 and transmits the power to the third arm portion 26. The first driving mechanism 27 causes the first arm portion 24 and the second arm portion 25 to pivot such that a connecting portion of the second arm portion 25 and the third arm portion 26 linearly moves on a virtual line parallel to the left-right direction.

The motor 30 is arranged inside the arm support portion 17. The speed reducer 31 configures a joint portion connecting the arm support portion 17 and the first arm portion 24. The speed reducer 32 configures a joint portion connecting the first arm portion 24 and the second arm portion 25. The motor 30 and the speed reducer 31 are connected via a pulley and a belt that are not illustrated and the motor 30 and the speed reducer 32 are connected via a pulley and a belt that are not illustrated. The motor 33 is arranged inside the second arm portion 25. The speed reducer 34 configures a joint portion connecting the second arm portion 25 and the third arm portion 26. The motor 33 and the speed reducer 34 are connected via a gear train that is not illustrated.

The hand driving mechanism 19 includes a motor 35, a speed reducer 36 that reduces speed of power of the motor 35 and transmits the power to the hand 14, a motor 37, and a speed reducer 38 that reduces speed of power of the motor 37 and transmits the power to the hand 15. The motors 35 and 37 and the speed reducers 36 and 38 are arranged inside the third arm portion 26. A base end of the hand 14 is connected to the speed reducer 36 via a pulley and a belt that are not illustrated and a base end of the hand 15 is connected to the speed reducer 38 via a pulley and a belt that are not illustrated.

As illustrated in FIG. 10 and FIG. 11, the arm lifting mechanism 21 includes a ball screw 39 arranged with the up-down direction serving as an axial direction, a motor 40 that rotates the ball screw 39, a nut member 41 that engages the ball screw 39, a guide rail 42 that guides the arm support portion 17 in the up-down direction, and a guide block 43. The arm lifting mechanism 21 is arranged inside the holding portion 18.

The ball screw 39 is pivotably held in a frame 44 that forms a part of the holding portion 18. A pulley 45 is fixed to a lower end of ball screw 39. The motor 40 is fixed to the frame 44. A pulley 46 is fixed to an output shaft of the motor 40. A belt 47 is stretched between the pulley 45 and the pulley 46. The guide rail 42 is fixed to the frame 44. The guide rail 42 is arranged such that s longitudinal direction of the guide rail 42 and the up-down direction are aligned. In this embodiment, the guide rails 42 are fixed at two locations on both left and right ends of the frame 44, respectively.

The nut member 41 is fixed to a fixing member 48 (see FIG. 11) that is fixed to a front side surface of the arm support portion 17. The guide blocks 43 are also fixed to the fixing member 48. The fixing member 48 has a protrusion 48a protruding rearward and a rear end surface of the protrusion 48a is fixed to the front side surface of the arm support portion 17. The fixing member 48 is covered by a cover 49 that forms a part of the holding portion 18. The cover 49 has a slit-like arrangement hole 49a where the protrusion 48a is arranged.

The arm lifting mechanism 21 causes the arm support portion 17 to move up and down between a lower limit position of the arm support portion 17 illustrated in FIG. 3 and an upper limit position of the arm support portion 17 illustrated in FIG. 4. When the arm support portion 17 is lowered to the lower limit position, an upper end surface of the holding portion 18 is above a lower surface of the first arm portion 24, as illustrated in FIG. 3. Specifically, the upper end surface of the holding portion 18 is above a lower surface of the base end portion of the first arm portion 24 that is pivotably connected to the upper end surface of the arm support portion 17.

When the arm support portion 17 is lowered to the lower limit position, the upper end surface of the holding portion 18 is below a lower surface of the third arm portion 26. In this embodiment, when the arm support portion 17 is lowered to the lower limit position, the top end surface of the holding portion 18 is slightly below an upper surface of the second arm portion 25. That is, when the arm support portion 17 is lowered to the lower limit position, the upper end surface of the holding portion 18 is between the upper surface of the second arm portion 25 and a lower surface of the second arm portion 25 in the up-down direction.

As illustrated in FIG. 1, the robot 13 includes two hands 52 and 53 on which the wafer 2 is mounted, an arm 54 to which the hand 52 is pivotably connected at a tip end thereof, an arm 55 to which the hand 53 is pivotably connected at a tip end thereof, an arm support portion 56 to which base ends of the arms 54 and 55 are pivotably connected, and a body portion 57 that holds the arm support portion 56 such that the arm support portion 56 can move up and down. A plurality of wafers 2 can be mounted on the hands 52 and 53.

The robot 13 also includes a hand driving mechanism (not illustrated) that causes the hand 52 to pivot relative to the arm 54, a hand driving mechanism (not illustrated) that causes the hand 53 to pivot relative to the arm 55, an arm driving mechanism (not illustrated) that drives the arm 54, an arm driving mechanism (not illustrated) that drives the arm 55, an arm support portion driving mechanism (not illustrated) that causes the arm support portion 56 to pivot relative to the body portion 57, and an arm lifting mechanism (not illustrated) that causes the arm support portion 56 to move up and down relative to the body portion 57.

As described above, the robot 13 is arranged with the lifting device 12 interposed between the robot 13 and the robot 5 in the left-right direction when viewed from the up-down direction. Specifically, as illustrated in FIG. 1, the robot 13 is arranged with the lifting device 12 interposed between the robot 13 and the robot 5 installed on the first floor of the processing unit 4 in the left-right direction. The robot 13 conveys the wafers 2 in and out of the storage portions 10 and 11.

Detailed Configuration of Hand

Detailed configurations of hands mounted on the robots 5 and the robot 13 will be described. The hands mounted on the robots 5 and the robot 13 may all have the same configuration and may have different configurations. In the following, a detailed configuration of a hand will be described using the hand 14 of the robot 5 as an example. In this specification, “secured” refers to a state where two components that are to be secured are firmly integrated by bonding, press-fitting, screwing, bolting, or the like.

The hand 14 is configured such that, as a mounting portion on which the wafer 2 is mounted, two types of mounting portions, that is, the grip wafer mounting portion 14a (see FIG. 8) prepared for holding the wafer 2 by a grip holding method and the suction wafer mounting portion 14c (see FIG. 5) prepared for holding the wafer 2 by a suction holding method, are attachable and removable thereto and therefrom (in other words, exchangeable). In the following, the hand 14 in a first form with the suction wafer mounting portion 14c loaded thereto will be described first. The hand 14 with the grip wafer mounting portion 14a loaded thereto will be described as the hand 14 in a second form.

As illustrated in FIG. 5, the hand 14 in the first form includes the suction wafer mounting portion 14c on which the wafer 2 is mounted and the support portion 14b that supports the suction wafer mounting portion 14c at a base end thereof. The hand 14 in the first form is formed in a linearly symmetrical manner with a predetermined axis serving as a symmetry axis when viewed from the up-down direction. A tip end of the suction wafer mounting portion 14c is formed into a bifurcated shape and a shape of the suction wafer mounting portion 14c when viewed from the up-down direction is approximately a Y shape. The suction wafer mounting portion 14c is formed into a flat plate shape.

On an upper surface of the tip end of the suction wafer mounting portion 14c that is formed into bifurcated shape, a suction pad 14c1 including a suction hole 14c3 through which a back surface of the wafer 2 mounted on the suction wafer mounting portion 14c is sucked to be held is provided. That is, two suction pads 14c1 are provided in the suction wafer mounting portion 14c. Inside the suction wafer mounting portion 14c, a mounting portion side flow path 14c2 connected to a corresponding one of the two suction holes 14c3 is formed. The two mounting portion side flow paths 14c2 are formed such that each of the two mounting portion side flow paths 14c2 extends from a position near a corresponding one of the suction holes 14c3 to a corresponding one of base ends 14cs on a support portion 14b side (see FIG. 6).

As illustrated in FIG. 6, the support portion 14b has a base 144a having approximately a flat plate shape and extending in parallel to the front-rear direction and the left-right direction. An upper surface of the base 144a has a recess 144b approximately at center thereof in the front-rear direction. A through hole 144c is formed at the rear end of the upper surface of the base 144a. The through hole 144c is connected to insides of the arm 16, the arm support portion 17, and the holding portion 18 illustrated in FIG. 4. At least two air pipes P are inserted through the through holes 144c. One of the two air pipes P passes through the insides of the arm 16, the arm support portion 17, and the holding portion 18 and is connected to an air suction source and an air supply source that are not illustrated via a solenoid valve. The other one of the two air pipes P passes through the insides of the arm 16, the arm support portion 17, and the holding portion 18 and is connected to the air suction source that is not illustrated.

The solenoid valve described above is controlled by a controller (processor) of the robot 5 that is not illustrated. This control allows one of the two air pipes P to switch between an air suction state and an air delivery state. In the robot 5 with the hand 14 in the first form loaded thereto, the two air pipes P are both connected to the air suction source. It is then allowed to switch between an air suction operation and a non-air suction operation.

In the hand 14 in the first form, the air suction source connected to the two air pipes P operates to suck air from the suction hole 14c3 facing the back surface of the wafer 2 mounted on the suction wafer mounting portion 14c. With this suction operation, the wafer 2 is held by suction on the suction pad 14c1. By stopping the operation of the air suction source, suction of the wafer 2 can be released.

A recess 144s (notch) is formed at each of both ends of a lower surface of a front end portion of the base 144a in the left-right direction. Each of the base ends 14cs of the suction wafer mounting portion 14c that have been formed into a bifurcated shape is stored in a corresponding one of the two recesses 144s and each of the base ends 14cs and a corresponding one of bottom surfaces of the recesses 144s are fixed with a bolt or the like.

Two air flow paths 144a2 extending in the front-rear direction are formed inside the front end portion of the base 144a so as to be spaced apart from each other in the left-right direction. Each of the two air flow paths 144a2 partially overlaps with a corresponding one of the recess 144s. In the bottom surface of each of the recesses 144s in the base 144a, a hole 144a1 that is connected to a corresponding one of the air flow paths 144a2 overlapping with the recess 144s is formed. Each of the two holes 144a1 communicates with a corresponding one of the mounting portion side flow paths 14c2 of the suction wafer mounting portion 14c. That is, in the hand 14 in the first form, one air suction flow path is formed by connecting the air flow path 144a2, the hole 144a1, the mounting portion side flow path 14c2, and the suction hole 14c3.

Two suction units 147 each including a connecting member 147a that connects a corresponding one of the two air flow paths 144a2 to a tip end 148a of a corresponding one of the air pipes P are secured to the recess 144b of the base 144a. Although not illustrated, in each of the two suction units 147, electronic components, such as various sensors that detect a pressure or the like of the air suction flow path described above, a controller that controls a flow rate of air passing through the air suction flow path, or the like, are stored. The air pipes P are configured to be attachable and removable to and from the suction units 147.

On the upper surface of the base 144a, two holes 144ha used for securing a housing 146K of the grip unit 146 that will be described below by bolts are formed between the two recesses 144s arranged to be aligned in the left-right direction with a space apart from each other. Also on a bottom surface of the recess 144b of the base 144a, four holes 144hb used for securing the housing 146K of the grip unit 146 by bolts are formed between the two suction units 147 arranged to be aligned in the left-right direction with a space apart from each other. The holes 144hb and the holes 144ha form an attachment portion used for attaching the grip unit 146 to the support portion 14b. That is, the support portion 14b is configured to allow the grip unit 146 to be attached to the attachment portion. The number of holes forming the attachment portion is not limited to six but can be any number.

As illustrated in FIG. 7, the grip unit 146 includes the housing 146K, an air cylinder 146a stored in the housing 146K, a roller 146c having a cylindrical shape, and a roller support member 146b that supports a rotation shaft of the roller 146c. The roller 146c extends in the up-down direction. The roller support member 146b freely rotatably supports the roller 146c at a front end portion thereof. A rear end portion of the roller support member 146b is supported by a piston rod 146a2 of the air cylinder 146a.

The air cylinder 146a includes intake and exhaust ports configured of an air supply port and an air exhaust port. A connector 146a1 is connected to each of the air supply port and the air outlet port. Each of the two connectors 146a1 can be connected to the tip end 148a of a corresponding one of the air pipes P. In a case where the hand 14 in the second form is loaded to the robot 5, one of the two air pipes P is connected to the air suction source and the other one of the two air pipes P is connected to the air supply source in accordance with control of the solenoid valve, allowing air supply and exhaust operations.

Although not illustrated, the housing 146K of the grip unit 146 further stores a controller that controls an air pressure, a regulator, a position detection mechanism that detects a position of the roller support member 146b in the front-rear direction, or the like. For the grip unit 146, a mechanism that moves the roller 146c and the position detection mechanism described above are needed, and therefore, the grip unit 146 includes more components than components of the suction unit 147, resulting in higher production costs.

In the hand 14 in the second form illustrated in FIG. 8, the grip wafer mounting portion 14a on which the wafer 2 is mounted is supported by the support portion 14b at a base end thereof. A tip end of the grip wafer mounting portion 14a is formed into a bifurcated shape and a shape of the grip wafer mounting portion 14a when viewed from the up-down direction is approximately a Y shape. The grip wafer mounting portion 14a is formed into a flat plate shape. A configuration of a base end portion of the grip wafer mounting portion 14a is approximately the same as that of the suction wafer mounting portion 14c. That is, the base end portion of the grip wafer mounting portion 14a is formed into a bifurcated shape and is secured to the recesses 144s of the support portion 14b by bolts.

An end surface abutting member 141 having a first abutting surface 141b1 that an end surface (outer peripheral surface) of the wafer 2 abuts and a second abutting surface 141a1 that the back surface of the wafer 2 abuts is fixed to an upper surface of the grip wafer mounting portion 14a at the tip end thereof formed into a bifurcated shape. That is, two end surface abutting members 141 are fixed to the grip wafer mounting portion 14a. A wafer placing member 142 on which the wafer 2 is placed is fixed at each of two locations on an upper surface of the grip wafer mounting portion 14a at the base end thereof. The wafer 2 is mounted on the end surface abutting members 141 and the wafer placing members 142. At the base end of the grip wafer mounting portion 14a, an opening 143 is provided between the two wafer placing members 142 aligned in the left-right direction.

In the hand 14 in the second form, the air cylinder 146a in the grip unit 146 operates to allow the roller 146c to press the end surface of the wafer 2. By the operation of the air cylinder 146a, the roller 146c is caused to move linearly between a pressing position where the roller 146c contacts the end surface of the wafer 2 to press the wafer 2 toward the first abutting surface 141b1, as indicated by a broken line in FIG. 8, and a retracted position where the roller 146c is retracted away from the end surface of the wafer 2, as indicated by a solid line in FIG. 8. By this operation, it is possible to hold the wafer 2 in the pressing position and release the wafer 2 from holding in the retracted position.

The hand 14 is sold, for example, as a single set including the support portion 14b and the suction wafer mounting portion 14c. In addition, as an optional item for the set, a set of the grip unit 146 and the grip wafer mounting portion 14a is sold. A user who purchased the support portion 14b and the suction wafer mounting portion 14c can use the hand 14 in the first form simply by loading the suction wafer mounting portion 14c to the support portion 14b. A user who additionally purchased the optional item can use the hand 14 in the second form illustrated in FIG. 8 by attaching the grip unit 146 to the support portion 14b and loading the grip wafer mounting portion 14a to the support portion 14b with the grip unit 146 attached thereto. Even after the grip unit 146 is attached, the hand 14 in the first form can be used by replacing the grip wafer mounting portion 14a with the suction wafer mounting portion 14c, as illustrated in FIG. 9. Although, in an example of FIG. 9, the suction wafer mounting portion 14c is loaded to the support portion 14b with the grip unit 146 attached to the support portion 14b, the grip unit 146 may be removed once, and then, the suction wafer mounting portion 14c may be loaded to the support portion 14b that does not have the grip unit 146 attached thereto.

Outline Operation of Manufacturing System

In the manufacturing system 1, a cassette (not illustrated) in which the plurality of wafers 2 are stored is arranged on right of the robot 13, and the robot 13 conveys the wafer 2 between the cassette and the storage portions 10 and 11. When the robot 13 conveys the wafer 2 in and out of the storage portion 10, the storage portion 10 is lowered to the lower limit position. The robot 5 that is installed on the second floor of the processing unit 4 conveys the wafer 2 between the processing device 3 that is installed on the second floor of processing unit 4 and the storage portion 10. At this time, the storage portion 10 is lifted to the upper limit position. The robot 5 that is installed on the first floor of the processing unit 4 conveys the wafer 2 between processing device 3 that is installed in the first floor of the processing unit 4 and the storage portion 11.

### Main Effects of this Embodiment

In accordance with the hand 14 described above, in the support portion 14b, only the suction unit 147 of the suction unit 147 and the grip unit 146 is provided, and an attachment portion used for attaching the grip unit 146 is further provided. Thus, manufacturing costs of the hand 14 can be reduced as compared to a configuration in which both the suction unit 147 and the grip unit 146 are secured to the support portion 14b in advance.

By attaching the grip unit 146 to the attachment portion afterward, it is possible to apply the hand 14 of this embodiment both to a case where it is desired to hold the wafer 2 by the grip holding method and a case where it is desired to hold the wafer 2 by the suction holding method. As a result, a user can purchase a single hand 14 and additionally purchase optional items to use the hand 14 in different ways for different purposes.

### Other Embodiments

Although the embodiment described above is an example of at least a preferred embodiment of the present invention, the present invention is not limited thereto but can be modified and implemented in various ways within a range that does not change the gist of the present invention.

For example, a configuration in which, in the support portion 14b, only the grip unit 146 of the suction unit 147 and the grip unit 146 is provided and an attachment portion used for attaching the suction unit 147 is further provided may be employed. Even with this configuration, the manufacturing costs for the hand 14 can be reduced.

In addition to the attachment portion used for attaching the grip unit 146, another attachment portion used for additionally attaching some other functional unit, such as a unit that realizes a mapping function that detects presence of the wafer 2 that has entered in a case that stores the wafer 2 or the like, may be provided in the support portion 14b. By doing so, a function of the hand 14 can be updated.

In the embodiment described above, the storage portion 11 may be fixed to a columnar member 60, and the storage portion 10 that is arranged above the storage portion 11 may be configured to move up and down between the first floor and the second floor of the processing unit 4. In addition to the above, for example, the storage portion 10 that is arranged above the storage portion 11 may be fixed to the columnar member 60 and the storage portion 11 may be configured to move up and down between the first floor and the second floor of the processing unit 4. In this case, the storage portion 10 is fixed in a position where the robot 5 that is installed on the second floor of the processing unit 4 can convey the wafer 2 in and out of the storage portion 10. In addition, in this case, the robot 13 is arranged with the lifting device 12 interposed between the robot 13 and the robot 5 that is installed on the second floor of processing unit 4 in the left-right direction. That is, in this case, the robot 13 is arranged at the same height as that of the second floor of the processing unit 4. The storage portion 10 in this case is a second storage portion.

In the embodiment described above, the lifting device 12 includes the storage portion 11, but the lifting device 12 may not include the storage portion 11. In this case, the lifting mechanism 61 causes the storage portion 10 to move up and down between a position where the robot 5 that is installed on the second floor of the processing unit 4 can convey the wafer 2 in and out of the storage portion 10 and a position where the robot 5 that is installed on the first floor of the processing unit 4 can convey the wafer 2 in and out of the storage portion 10. In this case, for example, the wafer 2 that has been processed by the processing device 3 that is installed on the first floor of the processing unit 4 can be stored in the storage portion 10 and conveyed directly to the second floor of the processing unit 4.

In the embodiment described above, the processing unit 4 includes two floors, but the processing unit 4 may include only one floor. In this case, the lifting device 12 is not needed. The processing unit 4 may include three or more floors. For example, the processing unit 4 may include three floors. In this case, for example, the lifting device 12 includes a storage portion that can move up and down between a first floor and a third floor of the processing unit 4 in addition to the storage portions 10 and 11 and, in addition to the lifting mechanism 61, a lifting mechanism that causes the storage portion to move up and down between the first floor and the third floor of the processing unit 4.

In a case where the processing unit 4 includes three floors, the lifting mechanism 61 may be used to cause the storage portion 10 to move up and down between a first floor and a third floor of the processing unit 4. That is, the storage portion 10 may be caused to move up and down to a position where the robot 5 that is installed on a second floor of the processing unit 4 can convey the wafer 2 in and out of the storage portion 10 and a position where the robot 5 that is installed on the third floor of the processing unit 4 can convey the wafer 2 in and out of the storage portion 10. Furthermore, in the case where the processing unit 4 includes three floors, the storage portion 10 may be fixed, the storage portion 11 may be caused to move up and down between the first floor and the second floor of the processing unit 4, and the lifting device 12 may include a storage portion that moves up and down between the second floor and the third floor of the processing unit 4.

In the embodiment described above, when the arm support portion 17 is lowered to the lower limit position, the upper end surface of the holding portion 18 is between the upper surface of the second arm portion 25 and the lower surface of the second arm portion 25 in the up-down direction. In addition to this, for example, when the arm support portion 17 is lowered to the lower limit position, the upper end surface of the holding portion 18 may be between an upper surface of the first arm portion 24 and the lower surface of the base end portion of the first arm portion 24 in the up-down direction. In the embodiment described above, the front side surface of the holding portion 18 is fixed to the fixing frame 7 of the processing unit 4, but the bottom surface of the holding portion 18 may be fixed to a floor surface of each floor of the processing unit 4. In the embodiment described above, the two hands 14 and 15 are attached to the tip end of the third arm portion 26, but the number of hands that are attached to the tip end of the third arm portion 26 may be one.

In the embodiment described above, six processing devices 3 are installed on each of the first floor and the second floor of the processing unit 4, but five or less processing devices 3 or seven or more processing devices 3 may be installed on each of the first floor and the second floor of the processing unit 4. In the embodiment described above, the processing device 3 is arranged at each of both the front and rear sides of the robot 5, but the processing device 3 may be arranged at only one of the front and rear sides of the robot 5. In the embodiment described above, the manufacturing system 1 is a semiconductor manufacturing system used for manufacturing a semiconductor, but the manufacturing system 1 may be a system used for manufacturing some other object than a semiconductor. That is, the robot 5 may be configured to convey some other object to be conveyed, such as a glass substrate or the like, than the wafer 2.

In this specification, at least the following items are described. Each element in parentheses indicates a corresponding component or the like in the embodiment described above, but is not limited thereto.

(1)

A hand (hand 14) for an industrial robot (robot 5) which includes a first mounting portion (grip wafer mounting portion 14a) on which an object to be conveyed (wafer 2) is mounted and that has an end surface abutting member (end surface abutting member 141) including an abutting surface (first abutting surface 141b1) that an end surface of the object to be conveyed abuts and a second mounting portion (suction wafer mounting portion 14c) on which the object to be conveyed (wafer 2) is mounted and that has a suction hole (suction hole 14c3) through which the object to be conveyed is sucked to be held, the first mounting portion and the second mounting portion being configured to be replaceable with each other,
the hand including
a support portion (support portion 14b) configured to support either the first mounting portion or the second mounting portion,
the support portion including
an air flow path (air flow path 144a2) connected to the suction hole in a state where the support portion supports the second mounting portion,
one of a first unit (suction unit 147) including a connecting member (connecting member 147a) that connects a tip end of an air pipe (air pipe P) stored in the industrial robot to the air flow path and a second unit (grip unit 146) that can press an end surface of the object to be conveyed that is mounted on the first mounting portion in a state where the support portion supports the first mounting portion, and
an attachment portion used for attaching the other one of the first unit and the second unit.

According to (1), in the support portion, one of the first unit and the second unit is provided and the attachment portion used for attaching the other one of the first unit and the second unit is provided. Thus, as compared to a configuration in which the support portion includes both the first unit and the second unit, manufacturing costs can be reduced. By attaching the other one of the first unit and the second unit to the attachment portion afterward, it is possible to apply the hand for an industrial robot both to a case where it is desired to use the first mounting portion to hold the object to be conveyed and a case where it is desired to use the second mounting portion to hold the object. As a result, a single hand can be used in different ways for different purposes. In a case where the attachment portion is used for attaching the second unit, one of a plurality of second units whose respective mechanisms are different may be selectively attached. Thus, flexible customization to meet user requirements can be realized.

(2)

The hand for an industrial robot described in (1), the hand being configured such that
the second unit has an air cylinder (air cylinder 146a), and
the air pipe is configured as a common air pipe to be connected to the connecting member of the first unit and intake and exhaust ports of the air cylinder.

According to (2), it is possible to hold the object to be conveyed in accordance with different methods simply by changing a connection target of the common air pipe between the first unit and the second unit. For example, assuming a configuration in which the support portion includes both the first unit and the second unit, a dedicated pipe is required for each unit. In contrast, according to (2), no dedicated pipe is required for each unit, and therefore, manufacturing costs for the industrial robot can be reduced.

(3)

The hand for an industrial robot described in (1) or (2), the hand being configured such that
the attachment portion is used for attaching the second unit.

According to (3), the second unit that has a more complex configuration than that of the first unit and requires higher costs than for the first unit is not provided in the support portion. Thus, manufacturing costs for the hand can be reduced.

(4)

An industrial robot including
the hand for an industrial robot described in any one of (1) to (3),
the air pipe,
an arm (arm 16) that supports the hand, and
an arm support portion (arm support portion 17) that supports the arm.

### DESCRIPTION OF REFERENCE NUMERALS

1 manufacturing system
2 wafer (semiconductor wafer)
3 processing device
4 processing unit
5 robot (horizontally articulated robot)
1 storage portion
11 storage portion (second storage portion)
12 lifting device
14, 15 hand
14a grip wafer mounting portion
14c suction wafer mounting portion
14b support portion
144a2 air flow path
147 suction unit
147a connecting member
146 grip unit
146a air cylinder
146c roller
P air pipe
16 arm
17 arm support portion
18 holding portion
19 hand driving mechanism
20 arm driving mechanism
21 arm lifting mechanism
24 first arm portion
25 second arm portion
26 third arm portion
27 first driving mechanism
28 second driving mechanism
61 lifting mechanism

1. A hand for an industrial robot which includes a first mounting portion on which an object to be conveyed is mounted and that has an end surface abutting member including an abutting surface that an end surface of the object to be conveyed abuts and a second mounting portion on which an object to be conveyed is mounted and that has a suction hole through which the object to be conveyed is sucked to be held, the first mounting portion and the second mounting portion being replaceable with each other, the hand comprising:
a support portion to support either the first mounting portion or the second mounting portion,
wherein the support portion includes
an air flow path connected to the suction hole in a state where the support portion supports the second mounting portion,
one of a first unit including a connecting member that connects a tip end of an air pipe stored in the industrial robot to the air flow path and a second unit that can press an end surface of the object to be conveyed that is mounted on the first mounting portion in a state where the support portion supports the first mounting portion, and
an attachment portion used for attaching the other one of the first unit and the second unit.

2. The hand for an industrial robot according to claim 1,
wherein the second unit has an air cylinder, and
the air pipe is configured as a common air pipe to be connected to the connecting member of the first unit and intake and exhaust ports of the air cylinder.

3. The hand for an industrial robot according to claim 1,
wherein the attachment portion is used for attaching the second unit.

4. An industrial robot comprising:
the hand for an industrial robot according to claim 1;
the air pipe;
an arm that supports the hand; and
an arm support portion that supports the arm.

5. The hand for an industrial robot according to claim 2,
wherein the attachment portion is used for attaching the second unit.
